(19) United States
(12) Patent Application Publication
(10) Pub. No.: US 2007/0256927 A1
(43) Pub. Date: Nov. 8, 2007

(54) Coating Apparatus for the Coating of a Substrate and also Method for Coating

(75) Inventor: Jorg Vetter, Bergisch Gladbach (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Metaplas Ionon Oberflaechenveredelungstechnik GmbH, Bergisch Gladbach (DE)

(21) Appl. No.: 11/630,594

(22) PCT Filed: May 6, 2005
(86) PCT No.: PCT/IB05/01655

§ 371 Date: Dec. 21, 2006

(30) Foreign Application Priority Data
Jun. 24, 2004 (EP) 04405394.0

(51) Int. Cl. C23C 14/00

(52) U.S. Cl. 204/192.12; 204/298.16

(57) ABSTRACT

The invention relates to a coating apparatus (1) with a process chamber (2) for the coating of substrate (S) by means of cathode sputtering, said process chamber (2) having an inlet (3) and an outlet (4) for a process gas, for setting up and maintaining a gas atmosphere, as well as an anode (5) and a cathode (6) with a target (61) of the target material (62) to be sputtered and an electrical energy source (7) for the generation of an electrical voltage between the anode (5) and the cathode (6), wherein the electrical energy source (7) includes an electrical sputtering source (8) with which the target material (62) of the cathode (6) can be transferred by sputtering into a vapour form. Furthermore, ionising means (9) are provided for the generation of an electrical ionisation voltage (91) so that the sputtered target material (62) can be at least partly ionised, with a filter device (10) with a magnetic guide component (11) being provided, said filter device (10) being designed and arranged in such a way that the sputtered ionised target material (622) can be supplied via the magnetic guide component (11) to a surface of the substrate (S) to be coated and that the sputtered non-ionised target material (623, 624) can be filtered out by the filter device (10) before reaching the surface of the substrate (S).

This application is a U.S. national phase of International Application No. PCT/IB2005/001655 filed May 6, 2005, which claims the priority of European Application No. 04405394.0 filed Jun. 24, 2004, the disclosures of both of which are incorporated herein by reference.

The invention relates to a coating apparatus for the coating of a substrate, to a method for the coating and also to a coated substrate in accordance with the preamble of the independent claim of the respective category.

A whole series of various chemical, mechanical and physical techniques are known from the prior art for the application of layers or layer systems to the most diverse substrates and have their justification and corresponding advantages and disadvantages depending on the requirement and their field of use.

For the application of relatively thin layers methods are in particular familiar in which the surface of a target is transformed in an electrical arc into the vapour form, with the vapour which is so formed then being able to precipitate as a coating on a substrate. Here, the methods of anodic and cathodic vacuum arc vaporisation are to be named. A disadvantage of these methods lies in the fact that on vaporising the target, for example the target which contains carbon or a metal, such as, for example, copper, macro-particles, so-called droplets, always occur which have to be filtered out in a complicated manner when, for example, highest demands with respect to quality are placed on the uniformity of the layer to be applied. As a rule, the filtering out of the droplets only succeeds to an insufficient degree, which naturally negatively influences the quality of the layers which arise.

Thus, in particular for demonstrating ultra thin defect-free layers, the known methods of cathode sputtering by means of an ionised process gas, such as in particular argon, are frequently used. The person skilled in the art is familiar with these sputtering methods in their diverse variants under the term “sputtering”.

The particle emission of droplets is by its very nature much smaller during sputtering than during arc vaporisation, because the target material is more carefully removed from the target and transferred into the vapour form by individual ionised atoms of the process gas under the action of an electrical field. I.e., during sputtering, the target material is not transferred into the gas phase by melting parts of the surface of the target as in arc vaporisation.

However, during sputtering, i.e. during the sputtering of the surface of a target by an ionised process gas, a certain danger of particle emissions through parasitic discharges arises, for example through the creation of so-called “micro-arcs” as a result of more or less spontaneous electrical discharges due to inhomogeneous electrical conditions. In this connection droplets of the size of ca. 10 nm to 500 nm can arise, amongst other things, as a result of the named parasitic discharges in the context of the particle emissions, with it also being possible for the size of the droplets to be significantly larger or smaller in certain cases.

The above named particle emissions are frequently not acceptable, even if these are significantly lower in comparison to the emissions during arc vaporisation from the point of view of their size and extent, in particular when manufacturing ultra thin layers or when extremely smooth surfaces are involved, such as for example of optical or electronic components, such as lenses or hard discs.

The object of the invention is thus to propose a coating apparatus and a method for coating by means of cathode sputtering with which the substrates, in particular optical, micromechanical and electronic components, can be coated largely free of defects, so that the coated surfaces satisfy the very highest quality requirements.

The subject matter of the invention which satisfies these objects from the point of view of the apparatus and from the point of view of the technical method are characterised by the features of the independent claim of the respective category.

The dependent claims relate to particularly advantageous embodiments of the invention.

The coating apparatus in accordance with the invention with a process chamber for the coating of a substrate by means of cathode sputtering, in which said process chamber has an inlet and an outlet for the process gas for the setting up and maintenance of a gas atmosphere, includes an anode and a cathode with a target of the target material to be sputtered, and an electrical energy source for the generation of an electrical voltage between the anode and the cathode, wherein the electrical energy source includes an electrical sputtering source with which the target material of the cathode can be transferred by sputtering into a vapour form. Furthermore, ionising means are provided for the generation of an electrical ionisation voltage so that the sputtered target material can be at least partly ionised, with a filter device with a magnetic guide component being provided, said filter device being designed and arranged so that the sputtered ionised target material can be supplied via the magnetic guide component to a surface of the substrate to be coated and the sputtered non-ionised target material can be filtered out by the filter device before reaching the surface of the substrate.

With the coating apparatus of the invention it is thus possible to supply essentially only the ionised part of the sputtered target material to a surface of the substrate to be coated and to filter out non-ionised components before they reach the substrate to be coated. In this way it is in particular possible to prevent a droplet-like collection of particles, so-called droplets, which have separated from the target at the cathode during the sputtering process, from reaching the surface of the substrate. In this connection the number of the ionised sputtered particles is massively increased in that the sputtered material, which is largely present in the gas phase, is ionised by the ionisation means by the application of an ionisation voltage, whereby the proportion of the ionised particles can lie up to 50%, depending on the way the process is conducted between 50% and 75%, and in a special case also above 75%. This can be achieved in that high, preferably pulsed ionisation voltages in the range of, for example, 1000 V are used with extremely high electrical currents of, for example, 1000 A for the ionisation. This corresponds to electrical powers in the megawatt range, with pulse frequencies of the ionisation voltage of up to a few KHz, preferably with pulse frequencies up to 100 Hz, especially for example with a pulse frequency of 50 Hz being used. This cathode sputtering technique which ionises sputtered target material of the cathode with the aid of ionisation means, a process which is familiar, amongst other things, under the term “post ionisation” is often termed “high-power sputtering”, a sputtering technique which is known per se and which is, for example, described in detail in WO 02/103078, in which the sputtered material, which is frequently electrically neutral to a large part, is post-ionised with high electrical powers.

The ionisation means can, for example, simply include a voltage source which is, for example, electrically connected to the anode and to the cathode so that, for example, a suitable pulsed voltage can be applied between the anode and the cathode, whereby sputtered target material can be ionised. In this connection the sputtering source and the ionisation means can be formed by one and the same voltage source which brings about a sputtering of the target and a post-ionisation of the sputtered material through suitable control and/or regulation of this voltage source, for example alternately or at the same time. Naturally, it is also possible for two or more voltage sources to be used, which can all be connected in common between the anode and the cathode with, for example, one voltage source serving only for the sputtering of the material and a further voltage source making available a suitable ionisation voltage for the post-ionisation of the sputtered target material.

Furthermore, the ionising means can naturally also include one or more suitable electrodes, so that the electrical ionisation voltage is wholly or partly isolated from the electrical sputtering source. For example, the ionisation means can include an electrode system galvanically separate from the anode and the cathode to which the electrical ionisation voltage can be applied for the post-ionisation.

The previously explained examples of ionisation means are naturally only to be understood by way of example, i.e. this listing of examples of possible embodiments of ionisation means is in no way exhaustive. On the contrary, it is essentially only important that an adequate degree of ionised target material is made available by the ionisation means which can then be supplied onto the substrate by means of the magnetic guide component for the coating. In special cases the post-ionisation can, for example, also be achieved by other ionisation sources, such as ionising radiation, for example X-ray radiation, laser radiation, or in other ways.

Through the massive increase of the degree of ionisation of the sputtered target material to a value of, for example, 70% ionised target material, one obtains an adequately high yield of coating material which can be supplied through the magnetic guide component of the filter device of the invention for the coating of the substrate at its surface via a predeterminable path. The non-ionised particles and particles such as, for example, the droplets, are essentially not capable of being influenced in their movement by the magnetic field of the magnetic guide component and are thus not directed through the filter device to the substrate to be coated.

In the simplest case the filter device is simply formed by one or more magnetic field generating sources which are the magnetic guide components which form a magnetic field for the guidance of the ionised sputtered particles designed such that these are guided by the magnetic field of the magnetic field generating sources on a predeterminable suitably curved track onto the surface of the substrate to be coated. The non-ionised particles, in particular the droplets which are essentially not ionised by the electrical ionisation voltage, are practically not influenced by the magnetic field of the magnetic guide component and thus do not follow the curved track of the magnetic field in their movement, so that the non-ionised particles do not reach the surface, but are rather deposited in the process chamber, for example on its walls or, for example, on suitably mounted collecting devices, for example sheet metal collectors or collecting diaphragms.

In a particularly preferred embodiment the filter means has at least one section in the form of a hose extending along the longitudinal axis, the section having an inlet opening and an outlet opening for the sputtered target material. In this connection the hose can consist of a single section or of a plurality of assembled sections which can be placed directly adjacent one another or arranged at a certain spacing from one another.

In a special case the hose can consist of a single suitably curved section, with the hose being so arranged with respect to the target or the cathode and with respect to the substrate that the sputtered particles enter through an inlet opening into the hose, with the ionised particles being so guided by the magnetic guide component in the hose so that they leave the hose again through an outlet opening in the direction of the substrate to be coated, so that the ionised particles in the hose can be guided onto the substrate by the magnetic guide component for the coating.

The non-ionised particles, such as for example the droplets, do not follow the curved shape and are thus deposited on the walls of the hose and do not reach the surface of the substrate to be coated. This variant of the coating apparatus of the invention has, amongst other things, the special advantage that the process chamber is essentially not contaminated by the target material deposited onto the substrate, or is only contaminated to a small degree. The hose is preferably so arranged in the process chamber that it can be exchanged without having to dismantle the magnetic guide component.

In a special embodiment the hose with the target and the sputtering source is so designed and arranged that the hose can essentially be provided for the outside of the process chamber and the outlet opening of the hose can cooperate with an opening of the process chamber in such a way that the ionised target material from the hose can be guided into the interior of the chamber for the coating of a substrate arranged in the process chamber. This variant has the special advantage that the coating chamber can be kept relatively small and the hose can be particularly easily exchanged.

If the hose consists of a plurality of individual sections which are, for example, arranged spaced apart from one another, the individual sections as such do not necessarily have to be curved. On the contrary, in a special embodiment, the arrangement of a plurality of sections forms in total a curved track which, through suitable design and arrangement of the magnetic guide component, is followed by the ionised particles in the direction towards the substrate. The individual sections can in this respect each, or only some of them, be made straight, although the total arrangement forms a more or less curved track. In this way it is, for example, possible, in the case of servicing, to exchange for example only individual sections. In particular, even complicated curvature geometries can easily be installed or dismantled by the sectionwise assembly of the arrangement.

In a preferred embodiment the hose has at least one bend with a predeterminable bend angle with respect to the longitudinal axis in a plane of curvature. Thus, the hose can, for example, be bent through any desired angle. Special bending angles lie below 45°, between 30° and 1800, preferably between 70° and 120°, and the hose can, in particular, have a bend of ca. 90°.

Particularly good filtering results can be achieved when the hose has a more complicated geometry of curvature. Thus, the hose can have a plurality of bends with respect to one plane of curvature which can eventually, but not necessarily, be directed in opposite directions. The hose can also have bends with respect to at least two different planes of curvature. Thus, for example, a spiral curvature is conceivable in a predeterminable section with respect to the longitudinal axis. However, in this connection, basically any suitable geometry is conceivable for the curvature of the hose which makes it possible to direct an adequately high proportion of the ionised sputtered particles onto the substrate to be coated.

The hose itself can, depending on the use and the requirements, consist of any suitable material and can be built up in any suitable manner. The hose is preferably, but not however necessarily, formed of suitable plastics or composite materials or can consist of metal or metal braids which can be magnetic or non-magnetic. If the hose itself is wholly or partly built up of magnetic materials then the hose itself can be part of the magnetic guide component and can contribute to the guidance of the ionised particles.

The magnetic guide component for the generation of a magnetic guide field which typically delivers field strengths of up to a few 1000 Gauss, especially up to 1000 Gauss, and in particular between 10 and 500 Gauss, can for example include an electrical magnetic coil, preferably a Helmholtz coil. In an example important in practice a plurality of coils are provided so that the magnetic field produced by the magnetic guide component can be particularly well matched to the ionised particles to be guided. Thus, for example, regulating means can be provided so that the shape and the strength of the magnetic guide field produced by the magnetic guide component can be controlled and/or regulated, both in dependence on the position and also in dependence on the time. Thus, it is for example possible to intentionally control and/or regulate the quantity of coating material which is intended to reach the substrate per unit of time by correspondingly controlling the magnetic field of the magnetic guide component, with the sputtering of the target being able to be continued further, for example under stable conditions.

In this connection it is possible, amongst other things, as will be described in more detail below, to coat different substrates by sputtering one and the same target under different conditions. Alternatively, however, one or the same substrate can for example be coated with coating material by sputtering two or more different targets, with the different targets in particular being able to consist of different target materials and with a separate filter device preferably leading to the substrate to be coated from each target. Thus, it is possible to intentionally coat a substrate with different materials or with the same materials simultaneously or one after the other, with the parameters of the layer to be deposited, such as for example the layer thickness or the layer composition, physical or chemical characteristics etc being capable of being set by control and/or regulation of the magnetic guide component in a particularly simple manner.

In this connection the magnetic guide component for the generation of a magnetic guide field can naturally also include one or more permanent magnets or form combinations of coils and permanent magnets or include wires through which current flows or any other suitable magnetic field generating component, with the magnetic guide component particularly also being able to include a pole shoe magnet which is well known to the person skilled in the art or any suitable combination of the named magnetic guide components.

In a preferred embodiment of the coating apparatus of the invention at least one retention diaphragm is provided as a particle trap for the filtering of non-ionised sputtered target material. This particle trap can, for example, be provided in the vicinity of the substrate at an outlet opening of the hose of the filter device. The particle trap can advantageously naturally also be arranged at any desired point inside the hose or, for example, as a retention diaphragm at the inlet opening of the hose. A plurality of particle traps can in particular be provided in one hose. In a special embodiment the inner side of the hose has a rib-like structure, said rib-like structure being so designed that it acts as particle trap so that non-ionised target material and/or also ionised or non-ionised process gas can be filtered out.

In one special embodiment the hose is completely absent and the filter device is formed only of a suitably arranged system of one or more particle traps in conjunction with the magnetic guide component.

It will be understood that all the previously described variants of particle traps can also be advantageously used in suitable combinations and that the listing of possible particle traps is not exhaustive.

For the control and/or regulation of the concentration of ionised process gas which can, for example be argon, another noble gas, or also any other suitable process gas, such as for example nitrogen, oxygen etc., an electron source for the injection of electrons can be provided for the neutralisation of the process gas, in particular for the neutralisation of argon, by which ions of the process gas and/or of the sputtered material can be neutralised, with the neutralisation of the sputtered materials preferably taking place at the end of the hose or at the end of the magnetic guide component.

In order to optimise the coating process of the substrate with ionised particles the substrate and/or a substrate holder for the substrate can be set to a predeterminable electrical positive or negative potential in a special embodiment.

For special applications the process chamber includes a sputtering chamber in which the cathode is arranged and a coating chamber in which the substrate is arranged. The sputtering chamber and the coating chamber are in this arrangement connected to one another by the filter device; with however also further connections being able to exist between the sputtering chamber and the coating chamber. In this arrangement the same gas atmosphere can prevail in the sputtering chamber and in the process chamber or, however, the gas atmosphere in the process chamber and in the sputtering chamber can differ from one another to a greater or lesser degree depending on the requirement, and corresponding means can be provided in order to eventually control and/or regulate the gas atmospheres in the respective chambers separately or jointly.

In this arrangement more than one cathode and/or more than one anode can also be provided in one and the same process chamber and/or in one and the same sputtering chamber, so that different cathodes of the same or different target material can be sputtered for example simultaneously or after one another so that, for example, one substrate can be coated simultaneously or in a predeterminable sequence with different materials.

Naturally, it is also possible for the coating apparatus to be designed such that at least two different substrates can be coated in one and the same coating chamber or in different coating chambers.

For this purpose a coating apparatus in accordance with the invention can include more than one sputtering chamber and/or more than one coating chamber.

As a target material for the coating of the substrate all suitable target materials can basically be considered, with the target preferably including carbon or carbon compounds or also metals or metal alloys, in particular copper.

In order to improve the sputtering characteristics of the coating apparatus of the invention it is preferable, however not essential, to provide a magnetic system including the cathode and corresponding cooling and holding means and for the magnetic system to be preferably formed as a magnetron, with the magnetron being able to be a balanced magnetron or an imbalanced magnetron. The incorporation and the use of magnetrons of all types is well known to the person skilled in the art in the context of the coating technique described here which is frequently termed “sputtering” and thus does not need to be described in detail.

It will be understood that the coating apparatus of the invention for the coating of a substrate is not restricted to certain sputtering techniques, i.e. to sputtering techniques. On the contrary, all variants of sputtering can advantageously be used in the coating apparatus in accordance with the invention, even if only the concentration of the ionised sputtered target material can be increased by the ionisation means to an adequate predeterminable concentration. In particular, the previously explained preferred embodiments of the coating apparatus of the invention are only by way of example and this listing should in no way be understood as exhaustive. On the contrary, all possible sensible combinations of the described embodiments for specific applications are likewise possible and can advantageously be used for the coating of substrates.

The method of the invention for the coating of a substrate by means of cathode sputtering is carried out in a coating apparatus with a process chamber, with the coating apparatus including a sputtering chamber with an inlet and an outlet for a process gas in which a gas atmosphere is set up. Furthermore, the coating apparatus includes an anode and a cathode with a target or a target material which is sputtered for the coating of the substrate and an electrical energy source with which an electrical voltage can be produced between the anode and cathode, with the electrical energy source having an electrical sputtering source with which the target material of the cathode can be transferred by sputtering into a vapour form and ionisation means is provided for the generation of an electrical lonisation voltage with which the sputtered target material is at least partly ionised. In this connection a filter device with a magnetic guide component is provided, said filter device being designed and arranged such that the sputtered ionised target material is at least partly supplied by the magnetic guide component to a surface of the substrate to be coated and a predeterminable proportion of the sputtered non-ionised target material is filtered out by the filter device before reaching the surface of the substrate.

In accordance with the invention a substrate, in particular an optical or an electronic component, especially a computer hard disc is coated by means of the coating apparatus of the invention and/or in accordance with the method of the invention. In this connection it is self-evident the method of the invention and the coating apparatus of the invention can be used to advantage apart from for the previously named special examples also for all other substrates, such as mechanical and technical components for which the highest quality requirements are placed on the coated surface or, for example, also in the field of aesthetic applications, such as for jewellery or ornamentations of all kinds.

In this connection the coating apparatus of the invention and the method of the invention can in particular be advantageously used in the field of micromechanics, of microelectronics, for example in medical technology, and/or for the coating of elements for nanosensors or for nanomotors.

The invention will be explained in more detail in the following with reference to the schematic drawing in which are shown:

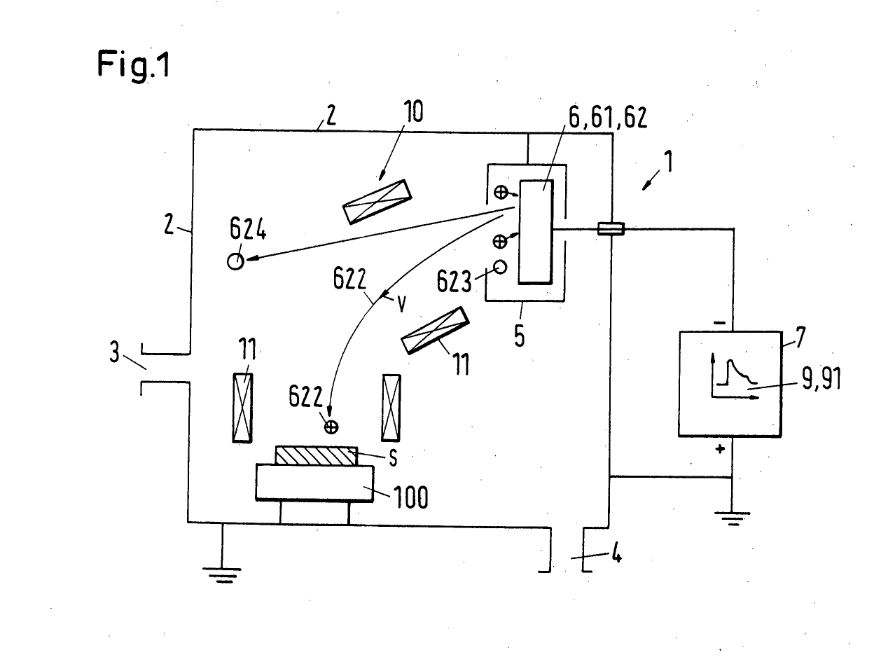

FIG. 1 a simple embodiment of a coating apparatus in accordance with the invention;

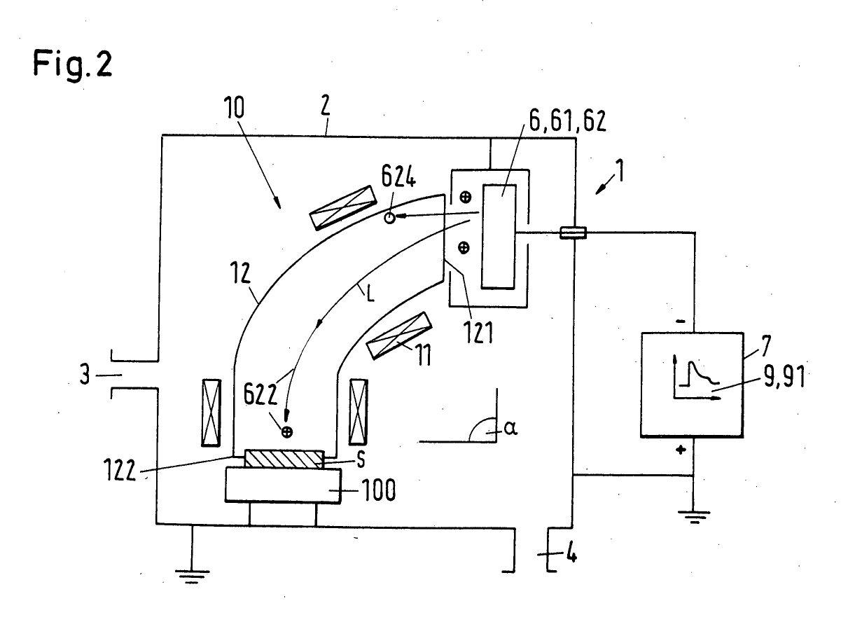

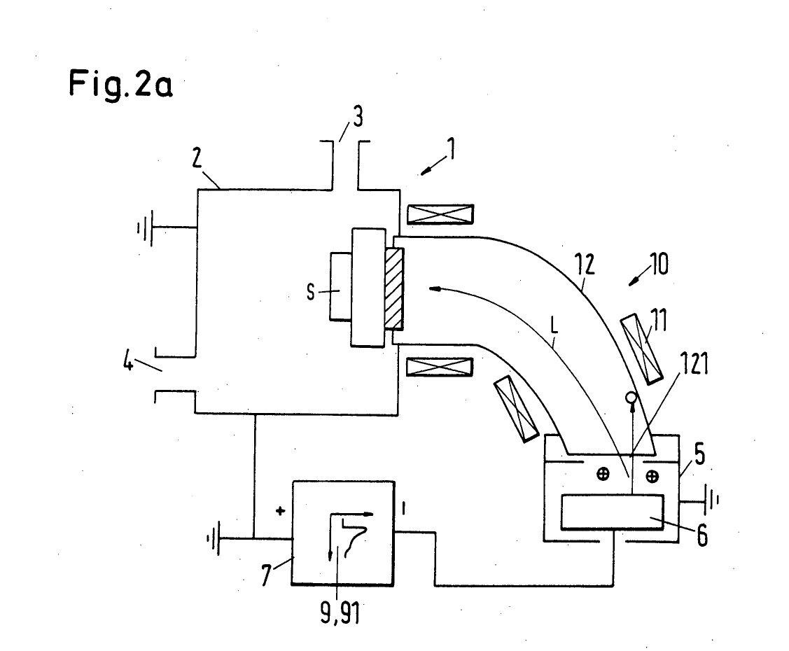

FIG. 2 a second embodiment in accordance with FIG. 1 with a hose;

FIG. 2a a hose arranged outside of the process chamber;

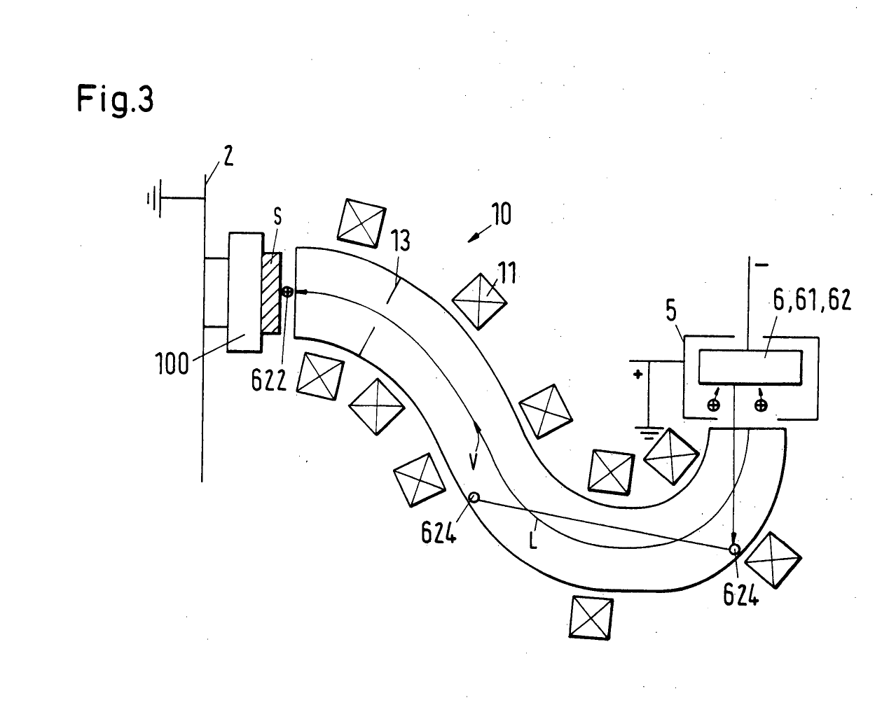

FIG. 3 a filter device with a multiply bent hose;

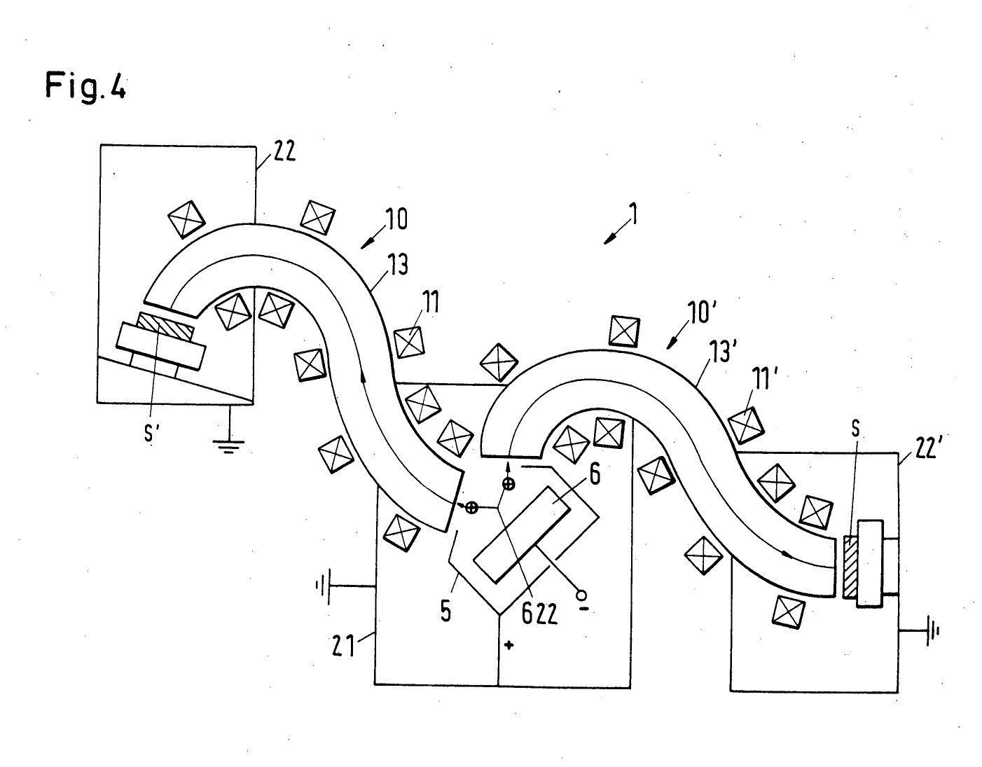

FIG. 4 a coating apparatus with a separate sputtering chamber and coating chamber;

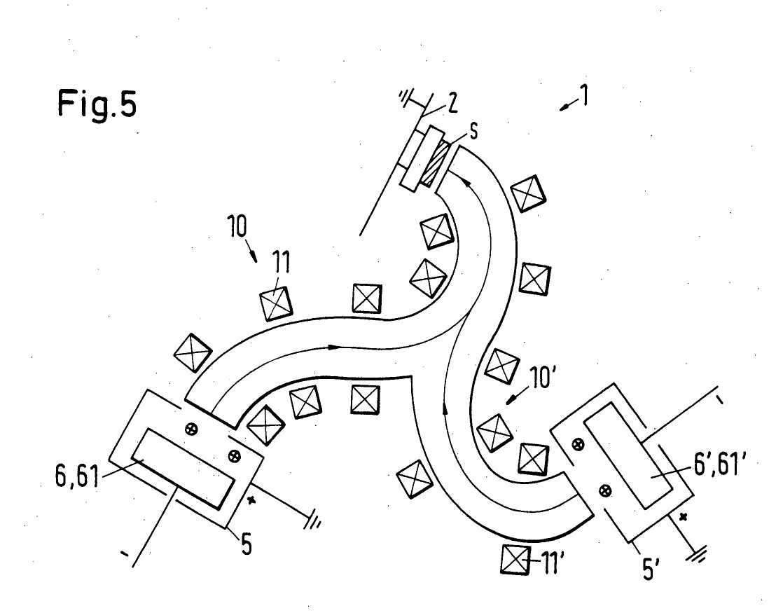

FIG. 5 a coating apparatus with two sputtering units.

FIG. 1 shows in a schematic representation a simple embodiment with a coating apparatus in accordance with the invention which is designated in the following with the reference numeral 1. The coating apparatus 1 for the coating of a substrate S, for example for the coating of a surface of a computer hard disc S or of a sensitive optical component S, includes a process chamber 2 for setting up and maintaining a gas atmosphere, said process chamber 2 having an inlet 3 and an outlet 4 for a process gas which, in the present case, is argon. In the coating apparatus 1 there is arranged an anode 5 and a cathode 6 which is connected to an electrical energy source 7 with an electrical sputtering source 8 and form a sputtering arrangement with which the target material 62 of the cathode can be transferred by sputtering into the vapour form.

In this process, which is well known as sputtering, ions of the process gas, i.e. here argon, are accelerated in the electrical field between the anode 5 and the cathode 6, with the positively charged ions of the process gas striking the negatively charged cathode 6 and thereby generating a small number of positively charged target ions 622 of the target material 62, a very much larger number of individual neutral atoms 623, i.e. non-ionised atoms 623 of the target material 62 from the target 61 and, for example, through micro-arcs, small essentially uncharged droplets 624 of the target material, so-called droplets 624.

Furthermore, a pulse-like, electrical ionisation voltage 91 which is generated by the ionisation means 9 is applied to the electrode pair of the anode 5 and cathode 6. The ionisation voltage 61 typically amounts to up to ca. 1000 V or more; currents of up to 1000 A or higher can arise, with typical pulse frequencies for the ionisation voltage 91 for example lying in the range of 50 Hz. Through the applied ionisation voltage 91 a considerable proportion of the non-ionised target atoms 623 knocked out from the target 61 is ionised so that positively charged target ions 622 arise from the non-charged target atoms 623. The degree of ionisation of the target material present in the vapour form which is achieved in this way can amount to 70% and more with corresponding process control.

Furthermore, the substrate S to be coated is arranged in the process chamber 2 on a substrate holder 100 which is either electrically insulated or, in a special case, can also be electrically conductingly connected to a wall of the process chamber 2 or to an electrical energy source, which is not shown here.

In accordance with the invention a filter device 10 is provided which, in the present case, includes only a magnetic guide device 11 as an important component. The magnetic guide device 11 includes two pairs of Helmholtz coils which are so designed and arranged that ionised target ions 622 which originate from the target with a speed V enter into the magnetic guide field of the magnetic guide device 11 produced by the Helmholtz coils and are supplied by the magnetic guide component 11 to a surface of the substrate S. Non-charged particles, and in particular the essentially non-charged droplets 624, cannot be influenced in their path by the magnetic guide field of the magnetic guide component 11 and are thus not guided by the magnetic guide component 11, i.e. here by the magnetic guide field produced by the Helmholtz coils, onto the surface of the substrate S to be coated. On the contrary, the uncharged droplets 624 follow their original direction and impinge either onto one of the Helmholtz coils or are, for example, deposited at a wall of the process chamber, whereby the droplets 624 are filtered out.

In FIG. 2 a further embodiment of FIG. 1 is shown, with the filter device 10 including, in addition to the magnetic guide components 11, a hose 12 extending along a longitudinal axis L. The ionised target material 622 sputtered from the target 61 and also the droplets 624 enter through the inlet opening 121 into the hose 12. The ionised particles 622 of the target material are guided by the magnetic guide component 11, as in the example of FIG. 1, onto the surface of the substrate S for the coating. The essentially uncharged droplets 624 are practically not influenced in their flight path by the magnetic guide component 11 and are deposited at the inner wall of the hose 12. Through the use of the hose 12 an even better filtering out of the droplets 624 is possible.

In this connection the filter action by the filter device 10 can be further improved by a more complicated design of the geometry of the hose 12. The hose 12 shown in FIG. 2 has in this connection a curvature a of ca. 90°. Naturally, the angle of curvature a can also have a larger or smaller value than 90°, depending on the requirement.

In FIG. 2a an embodiment of coating apparatus 1 in accordance with the invention is shown in which the hose 12 is arranged outside of the process chamber 2. The hose 12 with the target 6 and the sputtering source 8 is in this connection so designed and arranged that the hose 12 itself is essentially provided fully outside of the process chamber 2 and the outlet opening 121 of the hose 12 cooperates with an opening of the process chamber 2 in such a way that the ionised target material 622 from the hose 12 can be guided into the interior of the process chamber 2 for the coating of the substrate S arranged in the process chamber 2. This variant has the particular advantage that the coating chamber 2 can be kept relatively small and the hose 12 can be particularly easily exchanged.

Complicated geometries of the hose 12, such as for example the multiply bent hose 12 shown in FIG. 3, permit the manufacture of the most uniform layers of particularly high quality because droplets which could still reach the surface of the substrate S, e.g. after one reflection at a suitable point within the hose 12, can likewise be filtered out in the more complicated geometry of the hose 12 of FIG. 3. Furthermore, the guide device 10 can additionally include one or more retention diaphragms 13 as particle traps. In this connection the retention diaphragm 13 can be arranged in the hose 12, for example as is shown in FIG. 3. Moreover, it is possible for the hose to vary in diameter or shape along its longitudinal axis, whereby particle traps for the filtering out of undesired particles can likewise be realised, or the hose 12 can have a ribbed structure at its inner side which acts as a particle trap for non-ionised particles.

However, even in the embodiments of the coating apparatus 1 of the invention in which no hose 12 is provided, such as for example in the coating apparatus 1 of FIG. 1, suitable retention diaphragms 13 can be provided as particle traps for the droplets along the path of the ionised target material 622.

In FIG. 4 a coating apparatus 1 with a separate sputtering chamber 21 and two coating chamber 22, 22′ are shown by way of example. In the sputtering chamber 21 the anode 5 and the cathode 6 are so arranged that the target material 62 is sputtered in the sputtering chamber 21 and, as has already been explained in detail, is subsequently ionised. The ionisation means 9 are not shown in FIG. 4 for the sake of simplicity. Two substrates S and S′ to be coated are arranged in two different coating chambers 22 and 22′. The sputtering chamber 21 forms, together with the coating chambers 22 and 22′, as a whole the process chamber 2 of the coating apparatus 1. Each of the chambers can have its own inlet 3 and outlet 4 for a process gas, which are not shown here. In this connection it is possible to produce different gas atmospheres in the different chambers depending on the requirements. In particular, through suitable separate control and/or regulation of the two magnetic guide components 11 and 11′ of the two different filter devices 10 and 10′, the coating of the two substrates can be controlled independently of one another and independently of the sputtering of the target 61 in the sputtering chamber 21, so that, for example, a different coating from that applied to the substrate S′ can be applied to the substrate S, for example a coating with different characteristics or a different composition. Thus, amongst other things, the rate of the ionised particles available for the coating can be reduced in that the particle stream is partly so deflected in the hose 13, 13′ by a suitable setting of the magnetic guide field that it can be stopped prior to reaching the surface of the substrate S, S′ at a particle trap, not shown in FIG. 4, or however also by the walls of the hose 13, 13′.

It is also conceivable that a special controllable and/or regulatable electron source is provided, for example in the hose or from another suitable position, so that the concentration of the ions 622 of the target material in the hose can be set, whereby the progressing coating procedure can be set.

In this connection it is self-evident that for example also more than two coating chambers can also be provided or that different substrates S, S′ can be coated via different filter devices 10 and 10′ also in a common process chamber in which the sputtering arrangement consisting of the anode, cathode and ionisation means, can eventually also be accommodated.

In FIG. 5 a coating apparatus 1 with two sputtering arrangements with cathodes 6, 6′ and anodes 5, 5′ is shown. For reasons of simplicity the process chamber 2 is only illustrated by way of indication. The two sputtering arrangements with cathodes 6, 6′ and anodes 5, 5′ can in this connection each be accommodated in a separate sputtering chamber 21 (not shown in FIG. 5) and the substrate S can be arranged in a corresponding separate coating chamber 22, which is likewise not shown in FIG. 5. It will be understood that the two sputtering units can also be arranged in a common sputtering chamber 21 and the substrate can be placed in its own coating chamber 22. In a special case the total arrangement shown in FIG. 5 can also be accommodated in one and the same process chamber 2 or, for example, a sputtering unit together with the substrate S can be installed in a process chamber whereas the second sputtering unit is provided in a separate sputtering chamber 21.

In the embodiment of a coating apparatus in accordance with the invention in accordance with FIG. 5 the substrate can be coated simultaneously or in sequence with two like or different materials from two different targets. In this connection it is also possible here, depending on the requirements, and when the substrate or the sputtering units are arranged in different chambers to produce the same or different gas atmospheres in the different chambers.

In particular, through the suitable separate control and/or regulation of the two magnetic guide components 11, 11′ of the two different filter devices 10 and 10′ and/or of the two sputtering arrangements, the coating of the substrate can be controlled independently of one another and independently of the sputtering of the other respective targets 61, 61′, so that a high flexibility is achieved with respect to the layers to be applied to the substrate and their characteristics. Thus, for example, the rate of the ionised particles available for the coating from one of the two sputtering units can be reduced in that the particle flux is partly so deflected by suitable setting of the magnetic guide field that it can be stopped before reaching the surface of the substrate S at a particle trap, which is not illustrated in FIG. 5, or, however, by the walls of the hose 13, 13′, or, as previously explained, an electron source can be provided in the hose.

In this connection it is self-evident that, for example, different substrates S and S′ can also be coated, for example in that the embodiment of FIG. 4 is combined with the features of the example of FIG. 5. The substrate S can also be coated simultaneously or in sequence with more than two sputtering arrangements.

With the coating apparatus of the invention for the coating of a substrate by means of cathode sputtering an apparatus is thus available with which the most diverse substrates can be provided with layers which satisfy the highest quality requirements. In particular, ultrathin layers, such as are for example required in electronics, in optics, in micromechanics, in microelectronics or also in the field of nanosensors or in the technology of nanomotors or also in aesthetic or other applications, can be produced for the first time free of droplets by the use of the high-power sputtering technique known per se, with it not being possible to fully prevent the creation of the droplets, for example by micro-arc discharges during sputtering. Through the filter apparatus of the invention these droplets can, in particular, be reliably filtered out. Since essentially only the electrically charged ions of the coating material can reach the surface of the substrate to be coated through the guide field of the magnetic guide component, an activation and cleaning of the surfaces to be coated can be additionally achieved so that, with the coating apparatus of the invention and with the method of the invention, surfaces of very highest quality, which are practically completely free of faults, can be produced even in an extremely thin embodiment in the range of thickness of a few Angstrom up to a few nanometres, with the maximum layer thickness which can be produced naturally principally also being able to be significantly larger.

1. Coating apparatus for the coating of a substrate (1) by means of cathode sputtering including a process chamber (2) for setting up and maintaining a gas atmosphere and having an inlet (3) and an outlet (4) for a process gas as well as:
an anode (5) and a cathode (6) with a target (61) of the target material (62) to be sputtered;
an electrical energy source (7) for the generation of an electrical voltage between the anode (5) and the cathode (6), wherein
the electrical energy source (7) includes an electrical sputtering source (8) with which the target material (62) of the cathode (6) can be transferred by sputtering into a vapour form,
and wherein ionising means (9) are provided for the generation of an electrical ionisation voltage (91) so that the sputtered target material (62) can be at least partly ionised,
characterised in that a filter device (10) is provided with a magnetic guide component (11), said filter device (10) being designed and arranged so that the sputtered ionised target material (622) can be supplied via the magnetic guide component (11) to a surface of the substrate (1) to be coated and the sputtered non-ionised target material (623, 624) can be filtered out by the filter device (10) before reaching the surface of the substrate (S).

2. Coating apparatus in accordance with claim 1, wherein the filter device (10) has at least one section in the form of a hose (12) extending along a longitudinal axis (L) and having an inlet opening (121) and an outlet opening (122) for the sputtered target material (62).

3. Coating apparatus in accordance with claim 2, wherein the hose (12) has, with respect to the longitudinal axis (L), at least one bend with a predetermined angle of bend (a) in a plane of curvature.

4. Coating apparatus in accordance with claim 2, wherein the hose (12) has a plurality of bends in opposite directions with respect to a plane of curvature.

5. Coating apparatus in accordance with claim 2, wherein the hose (12) has bends with respect to at least two different planes of curvature.

6. Coating apparatus in accordance with claim 2, wherein the hose (12) is of spiral shape in a predetermined section with respect to the longitudinal axis (L).

7. Coating apparatus in accordance with claim 1, wherein the magnetic guide component (11) includes an electrical magnetic coil, preferably a Helmholtz coil, for the generation of a magnetic guide field.

8. Coating apparatus in accordance with claim 1, wherein the magnetic guide component (11) includes a permanent magnet for the generation of a magnetic guide field.

9. Coating apparatus in accordance with claim 1, wherein at least one retention diaphragm (13) is provided as a particle trap for the filtering of non-ionised sputtered target material (623, 624).

10. Coating apparatus in accordance with claim 1, wherein, for the neutralisation of the process gas and/or of the sputtered material, in particular for the neutralisation of argon, an electron source is provided for the injection of electrons with which ions of the process gas can be neutralised.

11. Coating apparatus in accordance with claim 1, wherein the substrate (1) and/or a substrate holder (100) can be set to a predeterminable electrically positive or negative potential.

12. Coating apparatus in accordance with claim 1, wherein the process chamber (2) includes a sputtering chamber (21) in which the cathode (6) is arranged and a coating chamber (22) in which the substrate (S) is arranged.

13. Coating apparatus in accordance with claim 1, wherein more than one cathode (6) and/or more than one anode (5) is provided.

14. Coating apparatus in accordance with claim 1, wherein the coating apparatus is designed such that at least two different substrates (S) can be coated.

15. Coating apparatus in accordance with claim 1, wherein more than one sputtering chamber (21) and/or more than one coating chamber (22) is provided.

16. Coating apparatus in accordance with claim 1, wherein the target (61) includes carbon or carbon compounds.

17. Coating apparatus in accordance with claim 1, wherein the target (61) includes metals or metal alloys, in particular copper.

18. Coating apparatus in accordance with claim 1, wherein a magnetron (600) is provided, preferably at the cathode (6).

19. Coating apparatus in accordance with claim 1, wherein a balanced magnetron (601) is provided, preferably at the cathode (6).

20. Coating apparatus in accordance with claim 1, wherein an imbalanced magnetron (602) is provided, preferably at the cathode (6).

21. Method for the coating of a substrate (S) by means of cathode sputtering in a coating apparatus (1) including:
a process chamber (2) with an inlet (3) and an outlet (4) for a process gas for the setting up of a gas atmosphere;
an anode (5) and a cathode (6) with a target (61) of a target material (62) which is sputtered for the coating of a substrate (S);
an electrical energy source (7) with which an electric potential can be produced between the anode (5) and the cathode (6), wherein
the electrical energy source (7) has an electrical sputtering source (8) with which the target material (62) of the cathode can be transferred by sputtering into a vapour form and
wherein an ionisation means (9) is provided for the generation of an electrical ionisation voltage (91) with which the sputtered target material (62) can be at least partly ionised,
characterised in that a filter device (10) is provided with a magnetic guide component (11), said filter device (10) being designed and arranged such that the sputtered ionised target material (622) is at least partly supplied by the magnetic guide component (1) to a surface of the substrate (S) to be coated and a predetermined proportion of the sputtered non-ionised target material (623, 624) is filtered out by the filter device (10) before reaching the surface of the substrate (S).

22. Substrate, in particular an optical or an electronic component, especially a hard disc of a computer, which is coated with a coating apparatus (1) in accordance with claim 21.
